(19) United States
(12) Patent Application Publication
(10) Pub. No.: US 2025/0146171 A1
(43) Pub. Date: May 8, 2025

(54) SILICON CARBIDE SUBSTRATE, METHOD OF MANUFACTURING SILICON CARBIDE SUBSTRATE, AND MANUFACTURING APPARATUS FOR SILICON CARBIDE SUBSTRATE

(71) Applicant: SUMITOMO ELECTRIC INDUSTRIES, LTD., Osaka (JP)

(72) Inventor: Shunsaku UETA, Osaka (JP)

(73) Assignee: SUMITOMO ELECTRIC INDUSTRIES, LTD., Osaka (JP)

(21) Appl. No.: 18/835,719

(22) PCT Filed: Jan. 12, 2023
(86) PCT No.: PCT/JP2023/000641

§ 371 Date: Aug. 3, 2024

(30) Foreign Application Priority Data
Feb. 17, 2022 (JP) 2022-022939

(51) Int. Cl. C30B 23/06; C30B 29/36

(52) U.S. Cl. CPC C30B 23/066; C30B 29/36

(57) ABSTRACT

A silicon carbide substrate is a silicon carbide substrate having a main surface and doped with vanadium. The main surface is constituted of an outer edge, an outer peripheral region that is a region within 5 mm from the outer edge, and a central region surrounded by the outer peripheral region. When the central region is divided into a plurality of square regions each having each side with a length of 5 mm, an electrical resistivity in each of the plurality of square regions is 1×10¹¹ Ωcm or more. An area density of micro-pipes in the central region is 1 cm2 or less.

### TECHNICAL FIELD

The present disclosure relates to a silicon carbide substrate, a method of manufacturing a silicon carbide substrate, and a manufacturing apparatus for a silicon carbide substrate. This application claims priority based on Japanese Patent Application No. 2022-022939 filed on Feb. 17, 2022, and the entire contents of the Japanese patent application are incorporated herein by reference.

### BACKGROUND ART

Japanese Unexamined Patent Application Publication No. 2010-77023 (Patent literature 1) discloses a silicon carbide single crystal having a vanadium concentration of 5×10¹⁴ cm⁻³ or more.

### CITATION LIST

### Patent Literature

Patent literature 1: Japanese Unexamined Patent Application Publication No. 2010-77023

### SUMMARY OF INVENTION

A silicon carbide substrate according to the present disclosure is a silicon carbide substrate having a main surface and doped with vanadium. The main surface is constituted of an outer edge, an outer peripheral region that is a region within 5 mm from the outer edge, and a central region surround by the outer peripheral region. When the central region is divided into a plurality of square regions each having each side with a length of 5 mm, an electrical resistivity in each of the plurality of square regions is 1×10¹¹ Ωcm or more. An area density of micropipes in the central region is 1 cm⁻² or less.

A method of manufacturing a silicon carbide substrate according to the present disclosure comprises the following steps. A first crucible in which silicon carbide powder and a silicon carbide seed crystal are disposed and a second crucible in which powder containing vanadium is disposed and which is connected to the first crucible are prepared. Each of the first crucible and the second crucible is heated. In the heating each of the first crucible and the second crucible, and the silicon carbide powder is sublimated and recrystallized on the silicon carbide seed crystal, so that a silicon carbide single crystal doped with vanadium grows on the silicon carbide seed crystal. A temperature of the powder containing vanadium is lower than a temperature of the silicon carbide powder.

A manufacturing apparatus for a silicon carbide substrate according to the present disclosure includes a first crucible, a second crucible, and a heater. Silicon carbide powder and a silicon carbide seed crystal are disposed in the first crucible. Powder containing vanadium is disposed in the second crucible. The second crucible is connected to the first crucible. The heater heats each of the first crucible and the second crucible such that a temperature of the powder containing vanadium is lower than a temperature of the silicon carbide powder.

### BRIEF DESCRIPTION OF THE DRAWINGS

FIG. 1 is a schematic plan view showing a configuration of a silicon carbide substrate according to an embodiment.

FIG. 2 is a schematic cross-sectional view taken along line II-II of FIG. 1.

FIG. 3 is a schematic plan view showing a measurement position of the vanadium concentration.

FIG. 4 is a schematic cross-sectional view showing a configuration of a manufacturing apparatus for a silicon carbide substrate according to an embodiment.

FIG. 5 is a schematic cross-sectional view showing a method for growing a silicon carbide single crystal according to an embodiment.

FIG. 6 is a schematic cross-sectional view showing a configuration of a manufacturing apparatus for a silicon carbide substrate according to a comparative example.

FIG. 7 is a schematic cross-sectional view showing a method for growing a silicon carbide single crystal according to a comparative example.

FIG. 8 is a view showing the distribution of electrical resistivity in a central region of a silicon carbide substrate according to sample 1.

FIG. 9 is a view showing the distribution of electrical resistivity in a central region of a silicon carbide substrate according to sample 2.

FIG. 10 is a view showing the distribution of electrical resistivity in a central region of a silicon carbide substrate according to sample 3.

FIG. 11 is a view showing the distribution of electrical resistivity in a central region of a silicon carbide substrate according to sample 4.

FIG. 12 is a view showing the distribution of micropipes in the central region of the silicon carbide substrate according to sample 1.

FIG. 13 is a view showing the distribution of micropipes in the central region of the silicon carbide substrate according to sample 2.

FIG. 14 is a view showing the distribution of micropipes in the central region of the silicon carbide substrate according to sample 3.

FIG. 15 is a view showing the distribution of micropipes in the central region of the silicon carbide substrate according to sample 4.

### DETAILED DESCRIPTION

### Problems to be Solved by the Present Disclosure

When the doping concentration of vanadium is increased during the growth of the silicon carbide single crystal, vanadium may exceed the solid solubility limit and precipitate from the silicon carbide single crystal. When vanadium is precipitated, the growth of the silicon carbide single crystal is inhibited, and thus a micropipe is easily formed in the silicon carbide single crystal. Therefore, it was difficult to obtain a silicon carbide substrate having a low area density of micropipes and a high electrical resistivity by increasing the vanadium concentration.

An object of the present disclosure is to provide a silicon carbide substrate having high electrical resistivity and low area density of micropipes, a method of manufacturing the silicon carbide substrate, and a manufacturing apparatus for the silicon carbide substrate.

### Effects of Present Disclosure

According to the present disclosure, a silicon carbide substrate having high electrical resistivity and low area density of micropipes, a method of manufacturing a silicon carbide substrate, and a manufacturing apparatus for a silicon carbide substrate can be provided.

### Description of Embodiments

First, embodiments of the present disclosure will be listed and described.

(1) A silicon carbide substrate 100 according to the present disclosure is silicon carbide substrate 100 having a main surface 10 and doped with vanadium. Main surface 10 is constituted of an outer edge 14, an outer peripheral region 11 that is a region within 5 mm from outer edge 14, and a central region 12 surround by outer peripheral region 11. When central region 12 is divided into a plurality of square regions 51 each having each side with a length of 5 mm, an electrical resistivity in each of the plurality of square regions 51 is 1×10¹¹ Ωcm or more. An area density of micropipes 1 in central region 12 is 1 cm⁻² or less. Accordingly, silicon carbide substrate 100 having high electrical resistivity and low area density of micropipes 1 can be obtained. Further, by setting the electrical resistivity in each of the plurality of square regions 51 to 1×10¹¹ Ωcm or more, the yield of the silicon carbide semiconductor device in which the leakage current is reduced can be improved.

(2) According to silicon carbide substrate 100 according to (1), when viewed in a direction perpendicular to main surface 10, a boundary between outer peripheral region 11 and central region 12 may include a first position 31, a second position 32 rotated by 90° clockwise from first position 31, a third position 33 rotated by 90° clockwise from second position 32, and a fourth position 34 rotated by 90° clockwise from third position 33. When a center of main surface 10 is defined as a fifth position 35, a vanadium concentration at each of first position 31, second position 32, third position 33, fourth position 34, and fifth position 35 may be 1×10¹⁷ cm⁻³ or more. Accordingly, the in-plane uniformity of the vanadium concentration can improve.

(3) According to silicon carbide substrate 100 according to (2), the vanadium concentration at each of first position 31, second position 32, third position 33, fourth position 34, and fifth position 35 may be 2×10¹⁷ cm⁻³ or more. As the vanadium concentration increases, the electrical resistivity of silicon carbide substrate 100 increases. By setting the vanadium concentration to 2×10¹⁷ cm⁻³ or more, the electrical resistivity can be further increased.

(4) According to silicon carbide substrate 100 according to (2) or (3), vanadium concentration at each of first position 31, second position 32, third position 33, fourth position 34, and fifth position 35 may be 3×10¹⁷ cm⁻³ or less. When the vanadium concentration exceeds the solid solubility limit, micropipe 1 is formed due to vanadium. By setting the vanadium concentration to 3×10¹⁷ cm⁻³ or less, the formation of micropipe 1 can be prevented.

(5) According to silicon carbide substrate 100 according to any one of (1) to (4), a number of micropipes 1 in each of the plurality of square regions 51 may be 2 or less. Accordingly, the reliability of the silicon carbide semiconductor device can improve.

(6) According to silicon carbide substrate 100 according to any one of (1) to (5), a nitrogen concentration at a center of main surface 10 may be 4×10¹⁶ cm⁻³ or more. When the nitrogen concentration included in silicon carbide substrate 100 is low, the electrical resistivity of silicon carbide substrate 100 is high. Therefore, even when the vanadium concentration is low, silicon carbide substrate 100 having high electrical resistivity can be obtained. On the other hand, when the nitrogen concentration included in silicon carbide substrate 100 is high, the electrical resistivity of silicon carbide substrate 100 is low. Therefore, in order to obtain silicon carbide substrate 100 having high electrical resistivity, it is necessary to increase the vanadium concentration. However, when the vanadium concentration is increased, micropipe 1 is easily formed.

According to silicon carbide substrate 100 described above, even when the nitrogen concentration is high, both high electrical resistivity and low area density of micropipes 1 can be achieved.

(7) According to silicon carbide substrate 100 according to any one of (1) to (6), an area density of threading screw dislocations 2 in central region 12 may be 1000 cm⁻² or less.

(8) According to silicon carbide substrate 100 according to any one of (1) to (7), an area density of threading edge dislocations 3 in central region 12 may be 1500 cm⁻² or less.

(9) According to silicon carbide substrate 100 according to any one of (1) to (8), a polytype of silicon carbide constituting silicon carbide substrate 100 may be 4H.

(10) A method of manufacturing silicon carbide substrate 100 according to the present disclosure includes the following steps. A first crucible 70 in which a silicon carbide powder 91 and a silicon carbide seed crystal 92 are disposed and a second crucible 80 in which a powder 93 containing vanadium is disposed and which is connected to first crucible 70 through a connection member 65 are prepared. Each of first crucible 70 and second crucible 80 is heated. In the heating each of first crucible 70 and second crucible 80, powder 93 containing vanadium is sublimated and introduced into first crucible 70 through connection member 65, and silicon carbide powder 91 is sublimated and recrystallized on silicon carbide seed crystal 92, so that a silicon carbide single crystal 94 doped with vanadium grows on silicon carbide seed crystal 92. In the heating each of first crucible 70 and second crucible 80, a temperature of powder 93 containing vanadium is lower than a temperature of silicon carbide powder 91.

According to the method of manufacturing silicon carbide substrate 100 described above, the temperature of powder 93 containing vanadium is lower than the temperature of silicon carbide powder 91. Thus, the vapor pressure of vanadium can be controlled at a low temperature. In the case of controlling the vapor pressure of vanadium at a low temperature, the variation in the vanadium concentration can be reduced as compared with the case of controlling the vapor pressure of vanadium at a high temperature. Therefore, it is possible to reduce the variation in the vanadium concentration doped in silicon carbide single crystal 94.

(11) According to the method of manufacturing silicon carbide substrate 100 of the (10), in the heating each of first crucible 70 and second crucible 80, a temperature of second crucible 80 may be controlled independently of a temperature of first crucible 70. Thus, the temperature of second crucible 80 in which powder 93 containing vanadium is disposed can be controlled with high accuracy.

(12) According to the method of manufacturing silicon carbide substrate 100 according to (10) or (11), powder 93 containing vanadium may be vanadium carbide.

(13) According to the method of manufacturing silicon carbide substrate 100 according to (10) to (12), in the heating each of first crucible 70 and second crucible 80, a difference between the temperature of powder 93 containing vanadium and a temperature of silicon carbide powder 91 may be 200° C. to 400° C.

(14) A manufacturing apparatus for silicon carbide substrate 100 according to the present disclosure includes first crucible 70, second crucible 80, and a heater 90. Silicon carbide powder 91 and silicon carbide seed crystal 92 are disposed in first crucible 70. Powder 93 containing vanadium is disposed in second crucible 80. Second crucible 80 is connected to first crucible 70. Heater 90 heats each of first crucible 70 and second crucible 80 such that a temperature of powder 93 containing vanadium is lower than a temperature of silicon carbide powder 91.

According to the manufacturing apparatus for silicon carbide substrate 100 described above, heater 90 heats each of first crucible 70 and second crucible 80 so that the temperature of powder 93 containing vanadium is lower than the temperature of silicon carbide powder 91. Thus, the vapor pressure of vanadium can be controlled at a low temperature. In the case of controlling the vapor pressure of vanadium at a low temperature, the variation in the vanadium concentration can be reduced as compared with the case of controlling the vapor pressure of vanadium at a high temperature. Therefore, it is possible to reduce the variation in the vanadium concentration doped in silicon carbide single crystal 94.

(15) According to the manufacturing apparatus for silicon carbide substrate 100 according to (14), heater 90 may include a first heater unit 74 configured to heat first crucible 70 and a second heater unit 81 configured to heat second crucible 80. Second heater unit 81 may be controlled independently of first heater unit 74. Thus, the temperature of second crucible 80 in which powder 93 containing vanadium is disposed can be controlled with high accuracy.

(16) According to the manufacturing apparatus for silicon carbide substrate 100 according to (14) or (15), the manufacturing apparatus may further include a heat insulator 75 disposed between first crucible 70 and second crucible 80. Thus, the temperature of each of first crucible 70 and second crucible 80 can be controlled with high accuracy.

### Detailed Description of Embodiments

Hereinafter, embodiments of the present disclosure (hereinafter, also referred to as the embodiments) will be described with reference to the drawings. In the following drawings, the same or corresponding portions are denoted by the same reference numerals, and description thereof will not be repeated. Regarding crystallographic indications in the present specification, an individual orientation is represented by [ ], a group orientation is represented by < >, an individual plane is represented by ( ) and a group plane is represented by { }. Generally, a negative index is supposed to be crystallographically indicated by putting “-” (bar) above a numeral but is indicated by putting the negative sign before the numeral in the present specification.

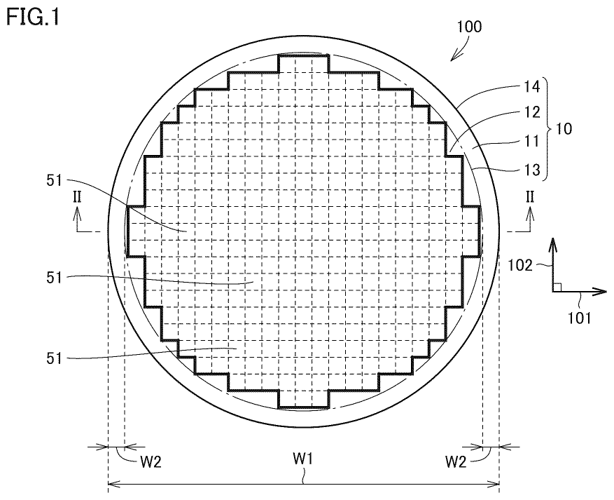

First, a configuration of silicon carbide substrate 100 according to an embodiment will be described. FIG. 1 is a schematic plan view showing a configuration of silicon carbide substrate 100 according to an embodiment.

As shown in FIG. 1, silicon carbide substrate 100 according to the embodiment has first main surface 10. The polytype of silicon carbide constituting silicon carbide substrate 100 is, for example, 4H. First main surface 10 is the {0001} plane or a plane tilted in the off direction with respect to the {0001} plane. In other words, first main surface 10 is the (0001) plane or a plane tilted in the off direction with respect to the (0001) plane. First main surface 10 may be the (000-1) plane or a plane tilted in the off direction with respect to the (000-1) plane.

First main surface 10 extends along each of a first direction 101 and a second direction 102. First direction 101 is not particularly limited, but is, for example, the <11-20> direction. Second direction 102 is not particularly limited, but is, for example, the <1-100> direction.

First direction 101 may be a direction obtained by projecting the <11-20> direction onto first main surface 10. From another viewpoint, first direction 101 may be the <11-20> direction including a direction component, for example. Similarly, second direction 102 may be a direction obtained by projecting the <1-100> direction onto first main surface 10, for example. From another viewpoint, second direction 102 may be the <1-100> direction including a direction component, for example.

When first main surface 10 is tilted in the off direction with respect to the (0001) plane, the off angle of first main surface 10 may be 8° or less. The off angle is not particularly limited, and may be, for example, 6° or less, or 4° or less. The off angle is not particularly limited, and may be, for example, 1° or more, or 2° or more. The off direction of first main surface 10 is not particularly limited, but is, for example, the <11-20> direction.

First main surface 10 is constituted of outer edge 14, outer peripheral region 11, and central region 12. Outer edge 14 is a boundary between first main surface 10 and an outer peripheral side surface 30. Outer peripheral region 11 is a region within the 5 mm from outer edge 14. Central region 12 is a region surrounded by outer peripheral region 11. Central region 12 is in contact with outer peripheral region 11.

A diameter W1 of first main surface 10 may be, for example, 100 mm or more, 150 mm or more, or 200 mm or more. Diameter W1 is not particularly limited, but may be, for example, 300 mm or less. When viewed in the direction perpendicular to first main surface 10, diameter W1 is the longest linear distance between two different points on outer edge 14.

As shown in FIG. 1, central region 12 is divided into the plurality of square regions 51. The side of each of the plurality of square regions 51 is 5 mm. Central region 12 is, for example, 105 mm in a direction passing through the center of first main surface 10 and parallel to first direction 101. First, a square of 105 mm×105 mm is assumed. The square of 105 mm×105 mm is divided into square regions 51 of 5 mm×5 mm (21×21=441).

In central region 12, the number of square regions 51 is, for example, 325. When viewed in the direction perpendicular to first main surface 10, square region 51 intersecting the boundary between central region 12 and outer peripheral region 11 is partially missing and does not become complete square region 51. Therefore, square region 51 intersecting the boundary is not regarded as square region 51 constituting central region 12. The sides of square region 51 are parallel to first direction 101.

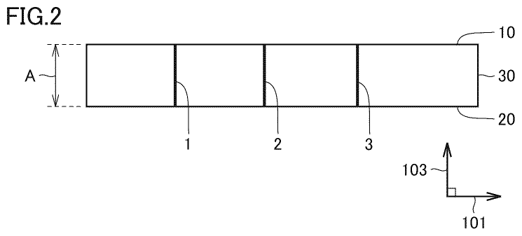

FIG. 2 is a schematic cross-sectional view taken along the line II-II of FIG. 1. The cross-sectional view shown in FIG. 2 is perpendicular to first main surface 10 and parallel to first direction 101. As shown in FIG. 2, silicon carbide substrate 100 according to the embodiment further includes a second main surface 20 and outer peripheral side surface 30. Second main surface 20 is opposite to first main surface 10. Outer peripheral side surface 30 is contiguous to each of first main surface 10 and second main surface 20.

As shown in FIG. 2, silicon carbide substrate 100 may include micropipes 1, threading screw dislocations 2, and threading edge dislocations 3. Each of micropipes 1, threading screw dislocations 2, and threading edge dislocations 3 extends from second main surface 20 to first main surface 10. A thickness A of silicon carbide substrate 100 is, for example, 300 μm to 700 μm. A third direction 103 is a direction perpendicular to each of first direction 101 and second direction 102. The thickness direction of silicon carbide substrate 100 is the same as third direction 103.

### (Electrical Resistivity of Silicon Carbide Substrate)

According to silicon carbide substrate 100 according to the embodiment, the electrical resistivity of silicon carbide substrate 100 in each of the plurality of square regions 51 is 1×10¹¹ Ωcm or more. In other words, the electrical resistivity of silicon carbide substrate 100 in all square regions 51 is 1×10¹¹ Ωcm or more. The electrical resistivity of silicon carbide substrate 100 in each of the plurality of square regions 51 is not particularly limited, but may be, for example, 3×10¹¹ Ωcm or more, or 5×10¹¹ Ωcm or more. The electrical resistivity of silicon carbide substrate 100 in each of the plurality of square regions 51 is not particularly limited, but may be, for example, 1×10¹³ Ωcm or less, or 1×10¹² Ωcm or less.

Next, a method for measuring the electrical resistivity of silicon carbide substrate 100 will be described. The electrical resistivity is measured by using, for example, COREMA-WT, which is an electrical resistivity measuring apparatus manufactured by Semimap Co., Ltd. Specifically, a voltage is applied to the object to be measured without contact using an electrode. As a result, the charge in the object to be measured increases with the passage of time. The charge of the portion of the object to be measured to which the voltage is applied is measured.

Specifically, the charge of the object to be measured immediately after the voltage is applied and the charge of the object to be measured at the time when a certain time has elapsed after the voltage is applied are measured. The relaxation time of the charge in the portion of the object to which the voltage is applied is measured. Thus, the electrical resistivity of the device under test is measured.

The electrical resistivity of silicon carbide substrate 100 is measured in each of the plurality of square regions 51 of silicon carbide substrate 100 according to the embodiment. The measurement interval is, for example, 5 mm. The voltage applied to silicon carbide substrate 100 is, for example, 5.0 V. The electrical resistivity of silicon carbide substrate 100 is measured at room temperature (25° C.), for example.

### (Vanadium Concentration)

Silicon carbide substrate 100 according to the embodiment is doped with vanadium. In silicon carbide substrate 100 according to the embodiment, the variation in the vanadium concentration is reduced in the plane of first main surface 10. Specifically, the variation in the vanadium concentration is reduced in each of the radial direction and the circumferential direction of first main surface 10.

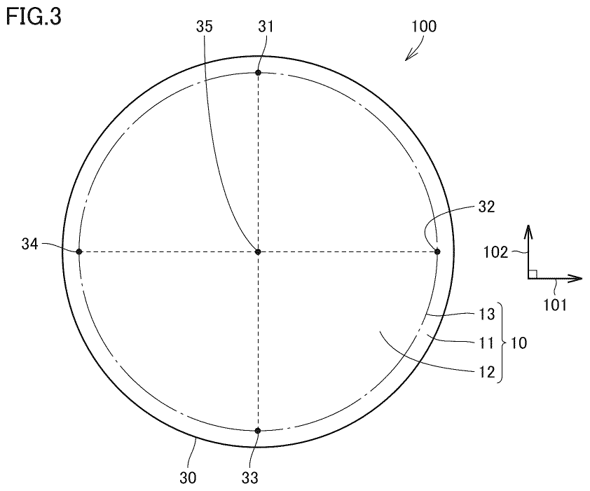

Next, a method for measuring the vanadium concentration will be described. FIG. 3 is a schematic plan view showing a measurement position of the vanadium concentration. As shown in FIG. 3, a boundary 13 between outer peripheral region 11 and central region 12 has first position 31, second position 32, third position 33, fourth position 34, and fifth position 35. When viewed in the direction perpendicular to first main surface 10, second position 32 is a position rotated by 90° clockwise from first position 31.

When viewed in the direction perpendicular to first main surface 10, third position 33 is a position rotated by 90° clockwise from second position 32. Fourth position 34 is a position rotated by 90° clockwise from third position 33 when viewed in the direction perpendicular to first main surface 10. The center of first main surface 10 is fifth position 35. Second position 32, fourth position 34, and fifth position 35 are positioned on a straight line parallel to first direction 101. First position 31, third position 33, and fifth position 35 are positioned on a straight line parallel to second direction 102.

The vanadium concentration at each of first position 31, second position 32, third position 33, fourth position 34, and fifth position 35 is, for example, 1×10¹⁷ cm⁻³ or more. The vanadium concentration at each of first position 31, second position 32, third position 33, fourth position 34, and fifth position 35 is not particularly limited, and may be, for example, 1.2×10¹⁷ cm⁻³ or more, 1.5×10¹⁷ cm⁻³ or more, or 2×10¹⁷ cm⁻³ or more.

The vanadium concentration at each of first position 31, second position 32, third position 33, fourth position 34, and fifth position 35 is, for example, 3×10¹⁷ cm⁻³ or less. The vanadium concentration at each of first position 31, second position 32, third position 33, fourth position 34, and fifth position 35 is not particularly limited, and may be, for example, 2.8×10¹⁷ cm⁻³ or less, or 2.6×10¹⁷ cm⁻³ or less.

Silicon carbide substrate 100 according to the embodiment contains, for example, nitrogen (N) as an n-type impurity. The nitrogen concentration at the center of first main surface 10 is, for example, 4×10¹⁶ cm⁻³ or more. The nitrogen concentration at the center of first main surface 10 is not particularly limited, and may be, for example, 4.2×10¹⁶ cm⁻³ or more, or 4.4×10¹⁶ cm⁻³ or more. The nitrogen concentration at the center of first main surface 10 is not particularly limited, but may be, for example, 1×10¹⁷ cm⁻³ or less, or 5×10¹⁶ cm⁻³ or less.

Silicon carbide substrate 100 according to the embodiment contains, for example, boron (B) as a p-type impurity. The boron concentration at the center of first main surface 10 is, for example, 1×10¹⁵ cm⁻³ or more. The boron concentration at the center of first main surface 10 is not particularly limited, and may be, for example, 1.3×10¹⁵ cm⁻³ or more, or 1.6×10¹⁵ cm⁻³ or more. The boron concentration at the center of first main surface 10 is not particularly limited, and may be, for example, 5×10¹⁵ cm⁻³ or less, or 3×10¹⁵ cm⁻³ or less.

Next, a method for measuring the impurity concentration will be described. The concentration of each of vanadium, nitrogen, and boron is measured by secondary ion mass spectrometry (SIMS). In SIMS, for example, IMS7f, which is a secondary ion mass spectrometer manufactured by Cameca Inc., can be used. As the measurement conditions in SIMS, for example, measurement conditions in which the primary ion is O₂⁺ and the primary ion energy is 8 keV can be used.

### (Micropipe)

Silicon carbide substrate 100 according to the embodiment may include micropipe 1. Micropipe 1 is a hollow crystal defect that penetrates silicon carbide substrate 100. When the polytype of silicon carbide constituting silicon carbide substrate 100 is 4H, micropipe 1 has a larger Burgers vector than 3c.

The area density of micropipes 1 in central region 12 is 1 cm⁻² or less. The area density of micropipes 1 in central region 12 is a value obtained by dividing the number of micropipes 1 in central region 12 by the area of central region 12. The area density of micropipes 1 in central region 12 is not particularly limited, and may be, for example, 0.9 cm⁻² or less, or 0.8 cm⁻² or less. The area density of micropipes 1 in central region 12 is not particularly limited, but may be, for example, 0.1 cm⁻² or more, or 0.2 cm⁻² or more.

The number of micropipes 1 in each of the plurality of square regions 51 is, for example, 2 or less. That is, the number of micropipes 1 in each of the plurality of square regions 51 is 0, 1, or 2. From another viewpoint, square region 51 in which the number of micropipes 1 is 3 or more may not be provided in central region 12.

### (Threading Screw Dislocation)

Silicon carbide substrate 100 according to the embodiment includes, for example, threading screw dislocations 2. The area density of threading screw dislocations 2 in central region 12 is, for example, 1000 cm⁻² or less. The area density of threading screw dislocations 2 in central region 12 is not particularly limited, and may be, for example, 900 cm⁻² or less, or 800 cm⁻² or less. The area density of threading screw dislocations 2 in central region 12 is not particularly limited, and may be, for example, 100 cm⁻² or more, or 200 cm⁻² or more.

### (Threading Edge Dislocation)

Silicon carbide substrate 100 according to the embodiment includes, for example, threading edge dislocation 3. The area density of threading edge dislocations 3 in central region 12 is, for example, 1500 cm⁻² or less. The area density of threading edge dislocations 3 in central region 12 is not particularly limited, but may be, for example, 1400 cm⁻² or less, or 1300 cm⁻² or less. The area density of threading edge dislocations 3 in central region 12 is not particularly limited, and may be, for example, 200 cm⁻² or more, or 400 cm⁻² or more.

Each of micropipes 1, threading screw dislocations 2, and threading edge dislocations 3 can be identified by, for example, a melt etching method. In the melt etching method, for example, a potassium hydroxide (KOH) melt is used. The temperature of the KOH melt is set to about 500° C. to 550° C. The etching time is set to be about 5 minutes to 10 minutes.

By immersing silicon carbide substrate 100 having each of micropipes 1, threading screw dislocations 2, and threading edge dislocations 3 in the KOH melt, etch pits originated by each of micropipes 1, threading screw dislocations 2, and threading edge dislocations 3 are formed in first main surface 10 of silicon carbide substrate 100. Threading edge dislocation 3 forms a small etch pit. Threading screw dislocation 2 forms a medium-sized etch pit. Micropipe 1 forms a large etch pit. The planar shape of each of micropipes 1, threading screw dislocations 2, and threading edge dislocations 3 is substantially hexagonal.

The size of the etch pit formed due to micropipe 1 is larger than the size of the etch pit formed due to threading screw dislocation 2. The size of the etch pit formed due to threading screw dislocation 2 is larger than the size of the etch pit formed due to threading edge dislocation 3. The length of the etch pit originated by threading screw dislocation 2 is typically about 30 μm to 50 μm. The length of the etch pit originated by threading edge dislocation 3 is typically about 15 μm to 20 μm.

Next, the etch pits formed in first main surface 10 are observed using, for example, a Nomarski differential interference microscope. Based on the shape and size of the etch pit, the number of each of micropipes 1, threading screw dislocations 2, and threading edge dislocations 3 is specified.

### (Manufacturing Apparatus for Silicon Carbide Substrate)

Next, a manufacturing apparatus 200 for silicon carbide substrate 100 according to the embodiment will be described.

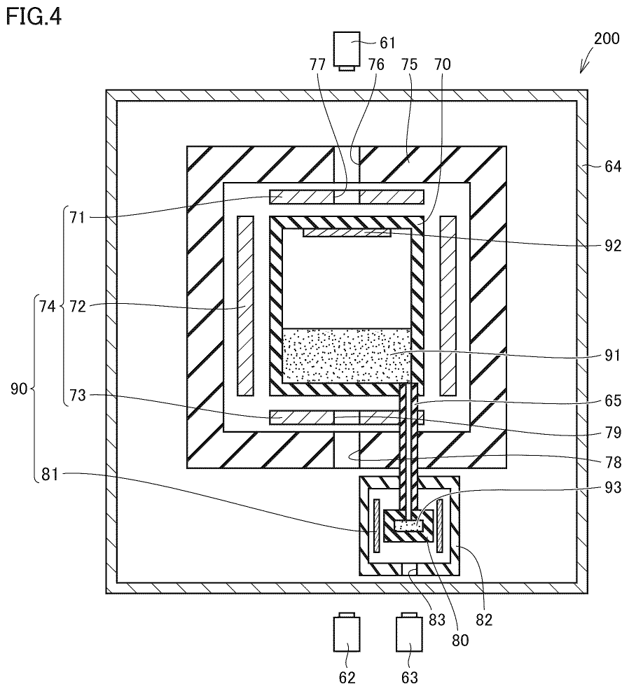

FIG. 4 is a schematic cross-sectional view showing a configuration of manufacturing apparatus 200 for silicon carbide substrate 100 according to an embodiment. As shown in FIG. 4, manufacturing apparatus 200 for silicon carbide substrate 100 according to the embodiment mainly includes first crucible 70, second crucible 80, heater 90, a chamber 64, connection member 65, first heat insulator 75, and a second heat insulator 82. First crucible 70 is made of, for example, graphite. Silicon carbide powder 91 and silicon carbide seed crystal 92 are disposed in first crucible 70.

Heater 90 includes first heater unit 74 and second heater unit 81. First heater unit 74 heats first crucible 70. Second heater unit 81 heats second crucible 80. First heater unit 74 includes, for example, an upper resistive heater 71, a lateral resistive heater 72, and a lower resistive heater 73. Upper resistive heater 71 is disposed above first crucible 70. A first through hole 77 is formed in upper resistive heater 71. Lateral resistive heater 72 is disposed to surround the outer circumferential surface of first crucible 70. Lower resistive heater 73 is disposed below first crucible 70. A second through hole 79 is formed in lower resistive heater 73.

First heat insulator 75 houses first crucible 70 and first heater unit 74. A third through hole 76 and a fourth through hole 78 are formed in first heat insulator 75. Third through hole 76 is located above first through hole 77. Fourth through hole 78 is located below second through hole 79.

Second crucible 80 is made of, for example, graphite. Powder 93 containing vanadium is disposed in second crucible 80. The volume of the internal space of second crucible 80 may be smaller than the volume of the internal space of first crucible 70. Second crucible 80 is connected to first crucible 70. Specifically, the internal space of second crucible 80 is connected to the internal space of first crucible 70 via the connection passage of connection member 65. Connection member 65 has, for example, a hollow cylindrical shape.

Second heat insulator 82 houses second crucible 80 and second heater unit 81. Second heater unit 81 surrounds the outer peripheral side surface of second crucible 80. First heat insulator 75 is disposed between first crucible 70 and second crucible 80. Similarly, second heat insulator 82 is disposed between first crucible 70 and second crucible 80. A fifth through hole 83 is provided below second heat insulator 82.

Connection member 65 penetrates through each of first heat insulator 75 and second heat insulator 82. One end of connection member 65 may be connected to a lower portion of first crucible 70. The connection passage of connection member 65 may be connected to the internal space of first crucible 70 at the boundary portion between the inner side surface and the inner bottom surface of first crucible 70. The other end of connection member 65 may be connected to the upper portion of second crucible 80. Chamber 64 houses first crucible 70, first heat insulator 75, second crucible 80, second heat insulator 82, and heater 90.

Manufacturing apparatus 200 for silicon carbide substrate 100 according to the embodiment further includes a first radiation thermometer 61, a second radiation thermometer 62, and a third radiation thermometer 63. First radiation thermometer 61 is disposed to face the upper surface of first crucible 70. First radiation thermometer 61 measures the temperature of the upper surface of first crucible 70 through first through hole 77 and third through hole 76. Second radiation thermometer 62 is disposed to face the lower surface of first crucible 70. Second radiation thermometer 62 measures the temperature of the lower surface of first crucible 70 through second through hole 79 and fourth through hole 78.

Third radiation thermometer 63 is disposed to face the lower surface of second crucible 80. Third radiation thermometer 63 measures the temperature of the lower surface of second crucible 80 through fifth through hole 83. First radiation thermometer 61, second radiation thermometer 62, and third radiation thermometer 63 are provided outside chamber 64.

Heater 90 heats each of first crucible 70 and second crucible 80 such that the temperature of powder 93 containing vanadium is lower than the temperature of silicon carbide powder 91. Specifically, each of first crucible 70 and second crucible 80 may be heated so that the temperature of the lower surface of second crucible 80 is lower than the temperature of the lower surface of first crucible 70.

Second heater unit 81 may be controlled independently of first heater unit 74. Specifically, the controlling method of the power applied to second heater unit 81 may be different from the controlling method of the power applied to first heater unit 74. The power source that applies power to second heater unit 81 may be different from the power source that applies power to first heater unit 74.

### (Method of Manufacturing Silicon Carbide Substrate)

Next, a method of manufacturing silicon carbide substrate 100 according to the embodiment will be described.

As shown in FIG. 4, silicon carbide powder 91 and silicon carbide seed crystal 92 are disposed inside first crucible 70. Silicon carbide seed crystal 92 is disposed in the upper portion of first crucible 70. Silicon carbide powder 91 is disposed in the lower portion of first crucible 70. Silicon carbide powder 91 is, for example, silicon carbide polycrystal. Powder 93 containing vanadium is disposed inside second crucible 80. Powder 93 containing vanadium is, for example, vanadium carbide powder. As shown in FIG. 4, first crucible 70 and second crucible 80 are connected by connection member 65.

As described above, first crucible 70 in which silicon carbide powder 91 and silicon carbide seed crystal 92 are disposed and second crucible 80 in which powder 93 containing vanadium is disposed and which is connected to first crucible 70 are prepared.

Next, a step of heating each of first crucible 70 and second crucible 80 is performed. First crucible 70 is heated mainly by first heater unit 74. Second crucible 80 is heated mainly by second heater unit 81. By heating first crucible 70, silicon carbide powder 91 disposed inside first crucible 70 is sublimated, and the sublimated gas is recrystallized on silicon carbide seed crystal 92. As a result, silicon carbide single crystal 94 is grown on silicon carbide seed crystal 92. As first crucible 70 is heated and second crucible 80 is heated, powder 93 containing vanadium disposed inside second crucible 80 is sublimated. Vanadium is doped into silicon carbide single crystal 94 grown on silicon carbide seed crystal 92.

In the step of heating each of first crucible 70 and second crucible 80, the temperature of powder 93 containing vanadium is lower than the temperature of silicon carbide powder 91. The temperature of the lower surface of second crucible 80 measured by third radiation thermometer 63 is estimated to be the temperature of powder 93 containing vanadium. The temperature of the lower surface of first crucible 70 measured by second radiation thermometer 62 is estimated to be the temperature of silicon carbide powder 91.

In the case of controlling the vapor pressure of vanadium at a low temperature, the variation in the vanadium concentration can be reduced as compared with the case of controlling the vapor pressure of vanadium at a high temperature. Therefore, it is possible to reduce the variation in the vanadium concentration doped in silicon carbide single crystal 94.

The temperature of powder 93 containing vanadium is, for example, 2200° C. to 2350° C. The temperature of powder 93 containing vanadium is not particularly limited, and may be, for example, 2220° C. or more, or 2240° C. or more. The temperature of powder 93 containing vanadium is not particularly limited, and may be, for example, 2320° C. or less, or 2280° C. or less.

The temperature of silicon carbide powder 91 is, for example, 2500° C. to 2600° C. The temperature of silicon carbide powder 91 is not particularly limited, and may be, for example, 2520° C. or more, or 2540° C. or more. The temperature of silicon carbide powder 91 is not particularly limited, and may be, for example, 2580° C. or less, or 2560° C. or less.

The difference between the temperature of powder 93 containing vanadium and the temperature of silicon carbide powder 91 is, for example, 200° C. or more. The difference between the temperature of powder 93 containing vanadium and the temperature of silicon carbide powder 91 may be, for example, 250° C. or more, or 300° C. or more. The difference in temperature between powder 93 containing vanadium and silicon carbide powder 91 is not particularly limited, but may be, for example, 400° C. or less.

In the step of heating each of first crucible 70 and second crucible 80, the temperature of second crucible 80 may be controlled independently of the temperature of first crucible 70. Specifically, the power applied to first heater unit 74 may be controlled based on the temperature of the upper surface of first crucible 70 measured by first radiation thermometer 61 and the temperature of the lower surface of first crucible 70 measured by second radiation thermometer 62. The power applied to second heater unit 81 may be controlled based on the temperature of the lower surface of second crucible 80 measured by third radiation thermometer 63.

In the step of heating each of first crucible 70 and second crucible 80, the pressure (growth pressure) of chamber 64 is at 50 Pa, for example. The pressure of chamber 64 may be, for example, 10 Pa to 100 Pa. The pressure of chamber 64 may be 80 Pa or less, or 60 Pa or less, but is not particularly limited thereto. The pressure of chamber 64 may be 20 Pa or more, or 40 Pa or more, but is not particularly limited thereto.

As described above, in the step of heating each of first crucible 70 and second crucible 80, silicon carbide powder 91 is sublimated and recrystallized on silicon carbide seed crystal 92, so that silicon carbide single crystal 94 doped with vanadium is grown on silicon carbide seed crystal 92.

When the temperature of first crucible 70 is low, vanadium is precipitated, and thus micropipe 1 is easily formed in silicon carbide single crystal 94. By maintaining the temperature of first crucible 70 high and reducing the growth pressure, vaporization of vanadium can be promoted. This can prevent the generation of micropipe 1 in silicon carbide single crystal 94.

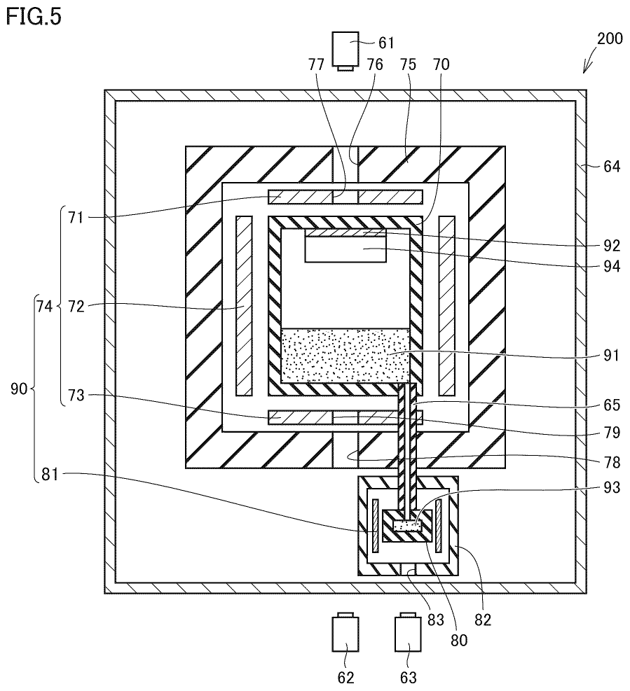

FIG. 5 is a schematic cross-sectional view showing a method for growing silicon carbide single crystal 94 according to an embodiment. As shown in FIG. 5, silicon carbide single crystal 94 is grown on silicon carbide seed crystal 92. After the growth of silicon carbide single crystal 94 is completed, silicon carbide single crystal 94 is cooled to room temperature. Next, silicon carbide single crystal 94 is sliced along a direction perpendicular to the growth direction by, for example, a saw wire. As a result, silicon carbide substrate 100 according to the embodiment is obtained (see FIG. 1).

Next, functions and effects of silicon carbide substrate 100 according to the embodiment will be described. In silicon carbide substrate 100 according to the embodiment, the electrical resistivity in each of the plurality of square regions 51 is 1×10¹¹ Ωcm or more. The area density of micropipes 1 in central region 12 is 1 cm⁻² or less. Accordingly, silicon carbide substrate 100 having high electrical resistivity and low area density of micropipes 1 can be obtained. Further, by setting the electrical resistivity in each of the plurality of square regions 51 to 1×10¹¹ Ωcm or more, the yield of the silicon carbide semiconductor device in which the leakage current is reduced can be improved.

According to silicon carbide substrate 100 according to the embodiment, the vanadium concentration at each of first position 31, second position 32, third position 33, fourth position 34, and fifth position 35 may be 1×10¹⁷ cm⁻³ or more. Accordingly, the in-plane uniformity of the vanadium concentration can improve.

Further, according to silicon carbide substrate 100 according to the embodiment, the vanadium concentration at each of first position 31, second position 32, third position 33, fourth position 34, and fifth position 35 may be 2×10¹⁷ cm⁻³ or more. As the vanadium concentration increases, the electrical resistivity of silicon carbide substrate 100 increases. By setting the vanadium concentration to 2×10¹⁷ cm⁻³ or more, the electrical resistivity can be further increased.

Further, according to silicon carbide substrate 100 according to the embodiment, the vanadium concentration at each of first position 31, second position 32, third position 33, fourth position 34, and fifth position 35 may be 3×10¹⁷ cm⁻³ or less. When the vanadium concentration exceeds the solid solubility limit, micropipe 1 is formed due to vanadium. By setting the vanadium concentration to 3×10¹⁷ cm⁻³ or less, the formation of micropipe 1 can be prevented.

Furthermore, according to silicon carbide substrate 100 according to the embodiment, the number of micropipes 1 in each of the plurality of square regions 51 may be 2 or less. Accordingly, the reliability of the silicon carbide semiconductor device can improve.

Further, according to silicon carbide substrate 100 according to the embodiment, the nitrogen concentration at the center of main surface 10 may be 4×10¹⁶ cm⁻³ or more. When the nitrogen concentration included in silicon carbide substrate 100 is low, the electrical resistivity of silicon carbide substrate 100 is high. Therefore, even when the vanadium concentration is low, silicon carbide substrate 100 having high electrical resistivity can be obtained. On the other hand, when the nitrogen concentration included in silicon carbide substrate 100 is high, the electrical resistivity of silicon carbide substrate 100 is low. Therefore, in order to obtain silicon carbide substrate 100 having high electrical resistivity, it is necessary to increase the vanadium concentration. However, when the vanadium concentration is increased, micropipe 1 is easily formed. According to silicon carbide substrate 100 according to the embodiment, even when the nitrogen concentration is high, both high electrical resistivity and low area density of micropipes 1 can be achieved.

According to the method of manufacturing silicon carbide substrate 100 according to the embodiment, the temperature of powder 93 containing vanadium is lower than the temperature of silicon carbide powder 91. Thus, the vapor pressure of vanadium can be controlled at a low temperature. In the case of controlling the vapor pressure of vanadium at a low temperature, the variation in the vanadium concentration can be reduced as compared with the case of controlling the vapor pressure of vanadium at a high temperature. Therefore, it is possible to reduce the variation in the vanadium concentration doped in silicon carbide single crystal 94.

Further, according to the method of manufacturing silicon carbide substrate 100 according to the embodiment, in the step of heating each of first crucible 70 and second crucible 80, the temperature of second crucible 80 may be controlled independently of the temperature of first crucible 70. Thus, the temperature of second crucible 80 in which powder 93 containing vanadium is disposed can be controlled with high accuracy.

According to manufacturing apparatus 200 for silicon carbide substrate 100 according to the embodiment, heater 90 heats each of first crucible 70 and second crucible 80 so that the temperature of powder 93 containing vanadium is lower than the temperature of silicon carbide powder 91. Thus, the vapor pressure of vanadium can be controlled at a low temperature. In the case of controlling the vapor pressure of vanadium at a low temperature, the variation in the vanadium concentration can be reduced as compared with the case of controlling the vapor pressure of vanadium at a high temperature. Therefore, it is possible to reduce the variation in the vanadium concentration doped in silicon carbide single crystal 94.

According to manufacturing apparatus 200 for silicon carbide substrate 100 according to the embodiment, heater 90 may include first heater unit 74 configured to heat first crucible 70 and second heater unit 81 configured to heat second crucible 80. Second heater unit 81 may be controlled independently of first heater unit 74. Thus, the temperature of second crucible 80 in which powder 93 containing vanadium is disposed can be controlled with high accuracy.

Further, according to manufacturing apparatus 200 for silicon carbide substrate 100 according to the embodiment, manufacturing apparatus 200 may further include heat insulator 75 disposed between first crucible 70 and second crucible 80. Thus, the temperature of each of first crucible 70 and second crucible 80 can be controlled with high accuracy.

### Example

### (Sample Preparation)

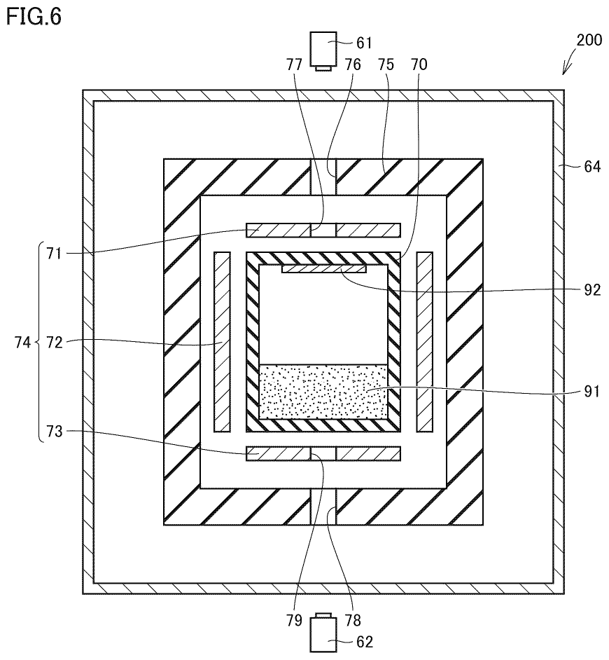

First, silicon carbide substrates 100 according to samples 1 to 4 were prepared. Samples 1 and 2 are comparative examples. Samples 3 and 4 are examples. Silicon carbide substrates 100 of samples 1 and 2 were fabricated using manufacturing apparatus 200 shown in FIG. 6.

FIG. 6 is a schematic cross-sectional view showing the configuration of manufacturing apparatus 200 for silicon carbide substrate 100 according to the comparative example. Manufacturing apparatus 200 for silicon carbide substrate 100 according to the comparative example is different from manufacturing apparatus 200 shown in FIG. 4 mainly in that second crucible 80, second heater unit 81, second heat insulator 82, connection member 65, and third radiation thermometer 63 are not provided, and other configurations are substantially the same as those of manufacturing apparatus 200 shown in FIG. 4. As shown in FIG. 6, manufacturing apparatus 200 for silicon carbide substrate 100 according to the comparative example includes first crucible 70, first heater unit 74, first heat insulator 75, chamber 64, first radiation thermometer 61, and second radiation thermometer 62.

As shown in FIG. 6, silicon carbide seed crystal 92 is disposed in the upper portion of first crucible 70. Silicon carbide powder 91 and the vanadium carbide powder are disposed in the lower portion of first crucible 70. The vanadium carbide powder is mixed with silicon carbide powder 91.

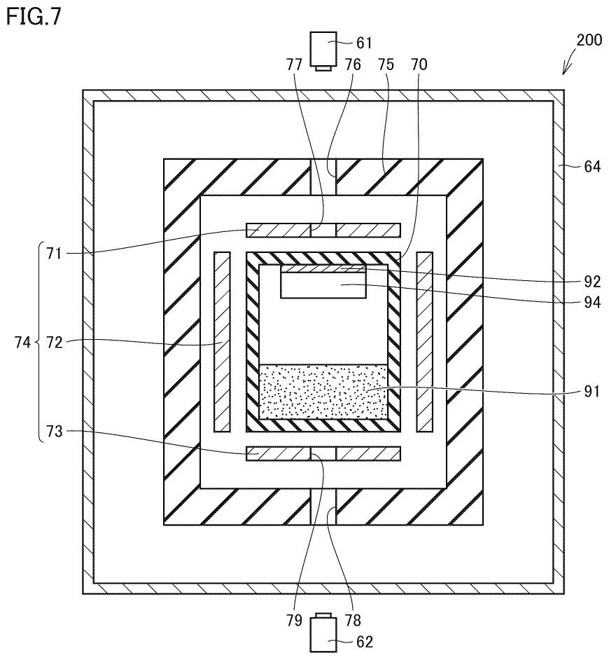

FIG. 7 is a schematic cross-sectional view showing a method of growing silicon carbide single crystal 94 according to the comparative example. As shown in FIG. 7, first crucible 70 is heated by first heater unit 74, whereby silicon carbide powder 91 disposed inside first crucible 70 is sublimated. Silicon carbide gas generated by sublimation of silicon carbide powder 91 grows on silicon carbide seed crystal 92. Vanadium is generated from vanadium carbide disposed inside first crucible 70. Vanadium is doped into silicon carbide single crystal 94. Accordingly, silicon carbide single crystal 94 doped with vanadium is grown on silicon carbide seed crystal 92. Grown silicon carbide single crystal 94 is sliced by a saw wire. Thus, silicon carbide substrate 100 according to the comparative example is obtained.

Silicon carbide substrates 100 of samples 3 and 4 were fabricated using manufacturing apparatus 200 shown in FIG. 4. The method of manufacturing silicon carbide substrate 100 according to samples 3 and 4 is as described above. The detailed manufacturing conditions of silicon carbide substrate 100 according to each of samples 1 to 4 are as follows.

TABLE 1

| | | | Temper- | Temper- | Temper- |
|---|---|---|---|---|---|
| | Type of | | ature | ature | ature |
| | Manufac- | Pres- | of Seed | of Silicon | of Vanadium |
| | turing | sure | Crystal | Carbide | Carbide |
| | Apparatus | (Pa) | (° C.) | (° C.) | (° C.) |
| Sample 1 | A (FIG. 6) | 1000 | 2300 | 2400 | 2400 |
| Sample 2 | A (FIG. 6) | 50 | 2450 | 2550 | 2550 |
| Sample 3 | B (FIG. 4) | 50 | 2450 | 2550 | 2300 |
| Sample 4 | B (FIG. 4) | 50 | 2450 | 2550 | 2250 |

As shown in Table 1, in the step of growing silicon carbide single crystal 94 according to sample 1, the pressure of chamber 64 was 1000 Pa. The temperature of the seed crystal was 2300° C. The temperature of the silicon carbide source material was 2400° C. The temperature of the vanadium carbide was 2400° C. In the step of growing silicon carbide single crystal 94 according to sample 2, the pressure of chamber 64 was 50 Pa. The temperature of the seed crystal was 2450° C. The temperature of the silicon carbide source material was 2550° C. The temperature of the vanadium carbide was 2550° C.

As shown in Table 1, in the step of growing silicon carbide single crystal 94 according to sample 3, the pressure of chamber 64 was 50 Pa. The temperature of the seed crystal was 2450° C. The temperature of the silicon carbide source material was 2550° C. The temperature of the vanadium carbide was 2300° C. In the step of growing silicon carbide single crystal 94 of sample 4, the pressure of chamber 64 was 50 Pa. The temperature of the seed crystal was 2450° C. The temperature of the silicon carbide source material was 2550° C. The temperature of the vanadium carbide was 2250° C.

### (Method for Measuring Electrical Resistivity)

The electrical resistivity of silicon carbide substrate 100 was measured at first main surface 10 of silicon carbide substrate 100 according to each of samples 1 to 4. The electrical resistivity was measured by using COREMA-WT, which is an electrical resistivity measuring apparatus manufactured by Semimap Co., Ltd. The voltage applied to the object to be measured was 5.0 V.

### (Measurement Results of Electrical Resistivity)

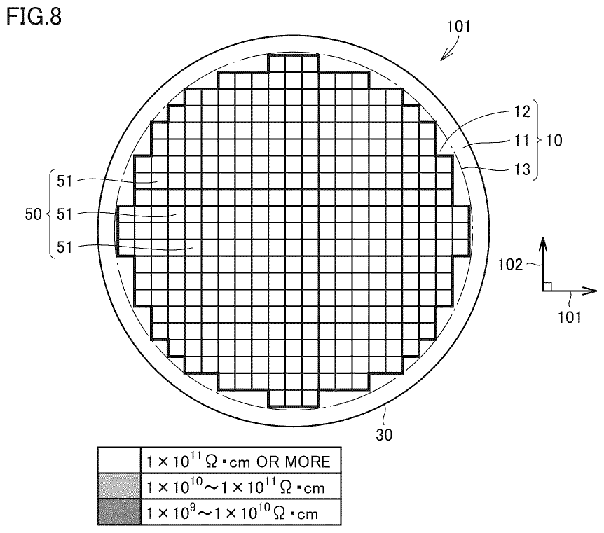

FIG. 8 is a view showing the distribution of electrical resistivity in central region 12 of silicon carbide substrate 100 according to sample 1. As shown in FIG. 8, the electrical resistivity of silicon carbide substrate 100 was 1×10¹¹ Ωcm or more in all square regions 51.

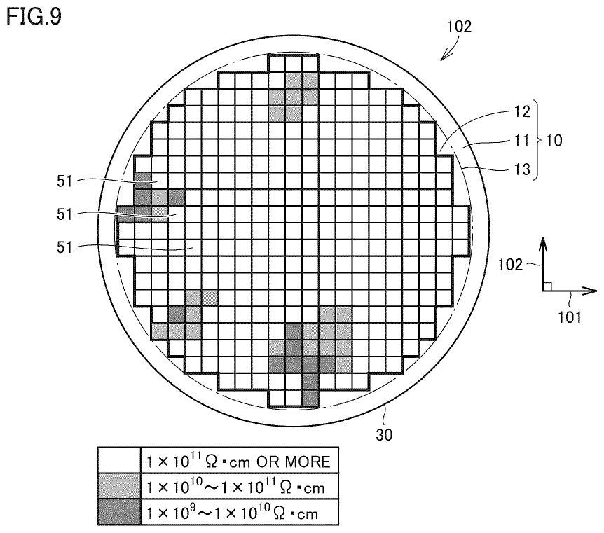

FIG. 9 is a view showing the distribution of electrical resistivity in central region 12 of silicon carbide substrate 100 according to sample 2. As shown in FIG. 9, the number of square regions 51 in which the electrical resistivity of silicon carbide substrate 100 was 1×10⁹ Ωcm or more and less than 1×10¹⁰ Ωcm was 14. The number of square regions 51 in which the electrical resistivity of silicon carbide substrate 100 was 1×10¹⁰ Ωcm or more and less than 1×10¹¹ Ωcm was 25. In other square regions 51, the electrical resistivity of silicon carbide substrate 100 was 1×10¹¹ Ωcm or more.

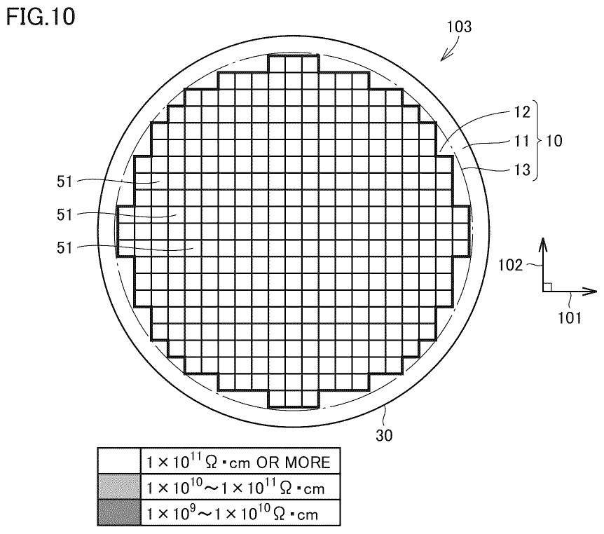

FIG. 10 is a view showing the distribution of electrical resistivity in central region 12 of silicon carbide substrate 100 according to sample 3. As shown in FIG. 10, the electrical resistivity of silicon carbide substrate 100 was 1×10¹¹ Ωcm or more in all square regions 51.

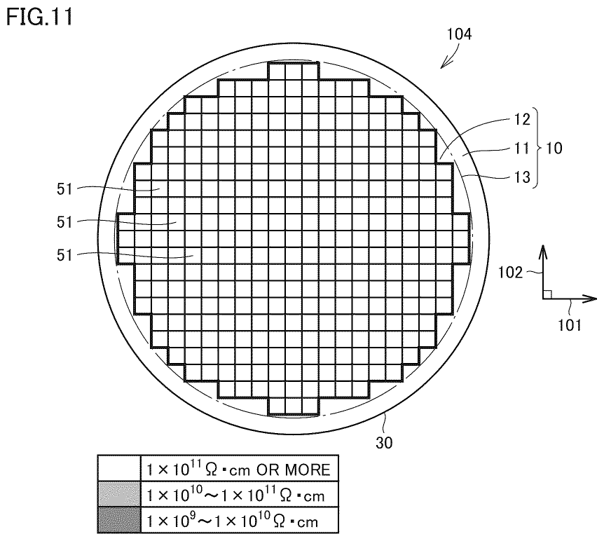

FIG. 11 is a view showing the distribution of electrical resistivity in central region 12 of silicon carbide substrate 100 according to sample 4. As shown in FIG. 11, the electrical resistivity of silicon carbide substrate 100 was 1×10¹¹ Ωcm or more in all square regions 51.

### (Method for Measuring Area Density)

Each of micropipes 1, threading screw dislocations 2, and threading edge dislocations 3 was identified by a melt etching method. In the melt etching method, a potassium hydroxide (KOH) melt was used. The temperature of the KOH melt was set to about 500° C. to 550° C. The etching time was set to about 5 minutes to 10 minutes. In central region 12, each of micropipes 1, threading screw dislocations 2, and threading edge dislocations 3 was identified. The area density of each of micropipes 1, threading screw dislocations 2, and threading edge dislocations 3 was determined by dividing the number of each of micropipes 1, threading screw dislocations 2, and threading edge dislocations 3 by dividing the area of central region 12.

### (Measurement Results of Area Density)

TABLE 2

| | | Area Density of | Area Density of |
|---|---|---|---|
| | Area Density of | Threading Screw | Threading Edge |
| | Micropipes | Dislocations | Dislocations |
| | (cm⁻²) | (cm⁻²) | (cm⁻²) |
| Sample 1 | 1.5 | 2600 | 5200 |
| Sample 2 | 0.8 | 900 | 1300 |
| Sample 3 | 0.9 | 900 | 1500 |
| Sample 4 | 0.5 | 700 | 1300 |

Table 2 shows the area density of each of micropipes 1, threading screw dislocations 2, and threading edge dislocations 3. As shown in Table 2, the area densities of micropipes 1 in central region 12 of silicon carbide substrates 100 according to samples 1 to 4 were 1.5 cm⁻², 0.8 cm⁻², 0.9 cm⁻², and 0.5 cm⁻², respectively. The area densities of threading screw dislocations 2 in central region 12 of silicon carbide substrates 100 according to samples 1 to 4 were 2600 cm⁻², 900 cm⁻², 900 cm⁻², and 700 cm⁻², respectively. The area densities of threading edge dislocations 3 in central region 12 of silicon carbide substrates 100 according to samples 1 to 4 were 5200 cm⁻², 1300 cm⁻², 1500 cm⁻², and 1300 cm⁻², respectively.

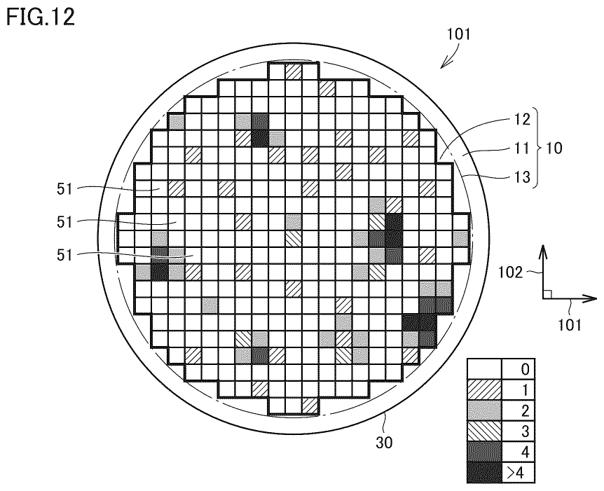

FIG. 12 is a view showing the distribution of micropipes 1 in central region 12 of silicon carbide substrate 100 according to sample 1. As shown in FIG. 12, the number of square regions 51 in which the number of micropipes 1 exceeded 4 was 6. The number of square regions 51 in which the number of micropipes 1 was 4 was 8. The number of square regions 51 in which the number of micropipes 1 was 3 was 5. The number of square regions 51 in which the number of micropipes 1 was 2 was 22. The number of square regions 51 in which the number of micropipes 1 was 1 was 27. In other square regions 51, micropipe 1 was not observed.

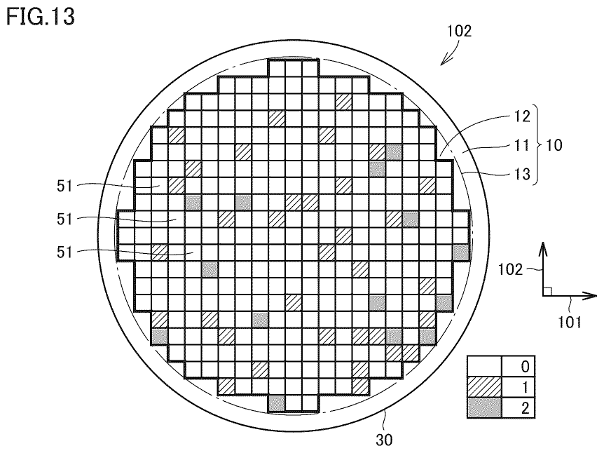

FIG. 13 is a view showing the distribution of micropipes 1 in central region 12 of silicon carbide substrate 100 according to sample 2. As shown in FIG. 13, the number of square regions 51 in which the number of micropipes 1 was 2 was 14. The number of square regions 51 in which the number of micropipes 1 was 1 was 34. In other square regions 51, micropipe 1 was not observed.

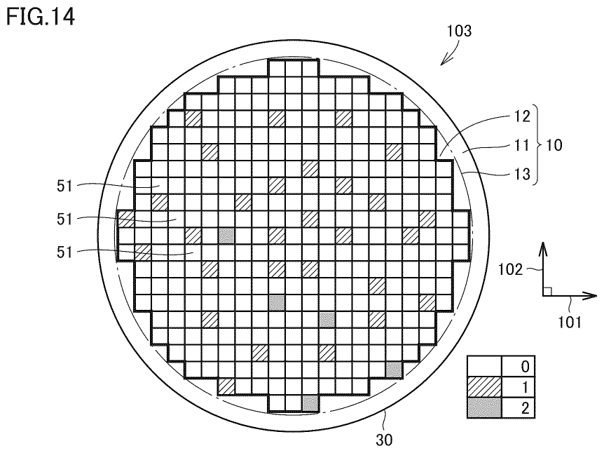

FIG. 14 is a view showing the distribution of micropipes 1 in central region 12 of silicon carbide substrate 100 according to sample 3. As shown in FIG. 14, the number of square regions 51 in which the number of micropipes 1 was 2 was 5. The number of square regions 51 in which the number of micropipes 1 was 1 was 29. In other square regions 51, micropipe 1 was not observed.

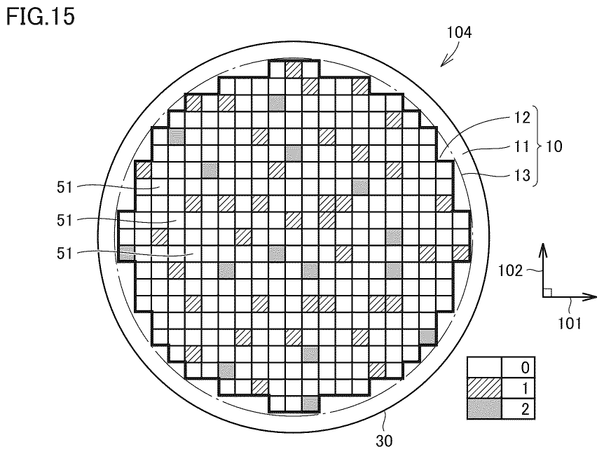

FIG. 15 is a view showing the distribution of micropipes 1 in central region 12 of silicon carbide substrate 100 according to sample 4. As shown in FIG. 15, the number of square regions 51 in which the number of micropipes 1 was 2 was 15. The number of square regions 51 in which the number of micropipes 1 was 1 was 38. In other square regions 51, micropipe 1 was not observed.

### (Method for Measuring Impurity Concentration)

The concentration of each of vanadium, nitrogen, and boron was measured by secondary ion mass spectrometry (SIMS). In SIMS, IMS7f, which is a secondary ion mass spectrometer manufactured by Cameca Inc., was used. The measurement conditions in SIMS were such that the primary ion was O₂⁺ and the primary ion energy was 8 keV.

### (Measurement Results of Impurity Concentration)

TABLE 3

| | Vanadium Concentration (cm⁻³) | | | | |
|---|---|---|---|---|---|
| | First | Second | Third | Fourth | Fifth |
| | Position | Position | Position | Position | Position |
| Sample 1 | 2.9 × 10¹⁷ | 2.6 × 10¹⁷ | 2.2 × 10¹⁷ | 2.5 × 10¹⁷ | 2.7 × 10¹⁷ |
| Sample 2 | 1.3 × 10¹⁷ | 0.87 × 10¹⁷ | 2.2 × 10¹⁷ | 0.76 × 10¹⁷ | 3.2 × 10¹⁷ |
| Sample 3 | 2.5 × 10¹⁷ | 2.1 × 10¹⁷ | 2.2 × 10¹⁷ | 2.5 × 10¹⁷ | 2.4 × 10¹⁷ |
| Sample 4 | 1.8 × 10¹⁷ | 1.8 × 10¹⁷ | 2.1 × 10¹⁷ | 1.9 × 10¹⁷ | 1.2 × 10¹⁷ |

Table 3 shows the vanadium concentration at each of first position 31, second position 32, third position 33, fourth position 34, and fifth position 35. As shown in Table 3, in silicon carbide substrate 100 according to each of samples 1, 3, and 4, the vanadium concentration at each of first position 31, second position 32, third position 33, fourth position 34, and fifth position 35 was 1×10¹⁷ cm⁻³ or more. On the other hand, in silicon carbide substrate 100 according to sample 2, the vanadium concentration at each of second position 32 and fourth position 34 was less than 1×10¹⁷ cm⁻³.

TABLE 4

| | Nitrogen | Boron |
|---|---|---|
| | Concentration | Concentration |
| | (cm⁻³) | (cm⁻³) |
| Sample 1 | 6.2 × 10¹⁶ | 2.8 × 10¹⁵ |
| Sample 2 | 4.8 × 10¹⁶ | 2.2 × 10¹⁵ |
| Sample 3 | 4.2 × 10¹⁶ | 1.8 × 10¹⁵ |
| Sample 4 | 4.5 × 10¹⁶ | 1.8 × 10¹⁵ |

Table 4 shows the nitrogen concentration and the boron concentration. As shown in Table 4, the nitrogen concentrations at the center of first main surface 10 of silicon carbide substrates 100 according to samples 1 to 4 were 6.2×10¹⁶ cm⁻³, 4.8×10¹⁶ cm⁻³, 4.2×10¹⁶ cm⁻³, and 4.5×10¹⁶ cm⁻³, respectively. The boron concentrations at the center of first main surface 10 of silicon carbide substrates 100 according to samples 1 to 4 were 2.8×10¹⁵ cm⁻³, 2.2×10¹⁵ cm⁻³, 1.8×10¹⁵ cm⁻³, and 1.8×10¹⁵ cm⁻³, respectively.

According to the above results, it was confirmed that silicon carbide substrate 100 in which the electrical resistivity in each of the plurality of square regions 51 is 1×10¹¹ Ωcm or more and the area density of micropipes 1 in central region 12 is 1 cm⁻² or less can be obtained by using the method of manufacturing silicon carbide substrate 100 according to the embodiment.

It should be understood that the embodiments and examples disclosed herein are illustrative in all respects and are not restrictive. The scope of the present invention is defined not by the embodiments described above but by the claims, and is intended to include meanings equivalent to the claims and all modifications within the scope.

### REFERENCE SIGNS LIST

1 micropipe, 2 threading screw dislocation, 3 threading edge dislocation, 10 first main surface (main surface), 11 outer peripheral region, 12 central region, 13 boundary, 14 outer edge, 20 second main surface, 30 outer peripheral side surface, 31 first position, 32 second position, 33 third position, 34 fourth position, 35 fifth position, 51 square region, 61 first radiation thermometer, 62 second radiation thermometer, 63 third radiation thermometer, 64 chamber, 65 connection member, 70 first crucible, 71 upper resistive heater, 72 lateral resistive heater, 73 lower resistive heater, 74 first heater unit, 75 first heat insulator (heat insulator), 76 third through hole, 77 first through hole, 78 fourth through hole, 79 second through hole, 80 second crucible, 81 second heater unit, 82 second heat insulator, 83 fifth through hole, 90 heater, 91 silicon carbide powder, 92 silicon carbide seed crystal, 93 powder, 94 silicon carbide single crystal, 100 silicon carbide substrate, 101 first direction, 102 second direction, 103 third direction, 200 manufacturing apparatus, A thickness, W1 diameter.

1. A silicon carbide substrate having a main surface and doped with vanadium,
wherein the main surface is constituted of an outer edge, an outer peripheral region that is a region within 5 mm from the outer edge, and a central region surround by the outer peripheral region,
when the central region is divided into a plurality of square regions each having each side with a length of 5 mm, an electrical resistivity in each of the plurality of square regions is 1×10¹¹ Ωcm or more, and
an area density of micropipes in the central region is 1 cm⁻² or less.

2. The silicon carbide substrate according to claim 1, wherein when viewed in a direction perpendicular to the main surface, a boundary between the outer peripheral region and the central region includes a first position, a second position rotated by 90° clockwise from the first position, a third position rotated by 90° clockwise from the second position, and a fourth position rotated by 90° clockwise from the third position, and
when a center of the main surface is defined as a fifth position, a vanadium concentration at each of the first position, the second position, the third position, the fourth position, and the fifth position is 1×10¹⁷ cm⁻³ or more.

3. The silicon carbide substrate according to claim 2, wherein the vanadium concentration at each of the first position, the second position, the third position, the fourth position, and the fifth position is 2×10¹⁷ cm⁻³ or more.

4. The silicon carbide substrate according to claim 2, wherein the vanadium concentration at each of the first position, the second position, the third position, the fourth position, and the fifth position is 3×10¹⁷ cm⁻³ or less.

5. The silicon carbide substrate according to claim 1, wherein a number of micropipes in each of the plurality of square regions is 2 or less.

6. The silicon carbide substrate according to claim 1, wherein a nitrogen concentration at a center of the main surface is 4×10¹⁶ cm⁻³ or more.

7. The silicon carbide substrate according to claim 1, wherein an area density of threading screw dislocations in the central region is 1000 cm⁻² or less.

8. The silicon carbide substrate according to claim 1, wherein an area density of threading edge dislocations in the central region is 1500 cm⁻² or less.

9. The silicon carbide substrate according to claim 1, wherein a polytype of silicon carbide constituting the silicon carbide substrate is 4H.

10. A method of manufacturing a silicon carbide substrate, the method comprising:
preparing a first crucible in which silicon carbide powder and a silicon carbide seed crystal are disposed and a second crucible in which powder containing vanadium is disposed and which is connected to the first crucible through a connection member; and
heating each of the first crucible and the second crucible,
wherein in the heating each of the first crucible and the second crucible, the powder containing vanadium is sublimated and introduced into the first crucible through the connection member, and the silicon carbide powder is sublimated and recrystallized on the silicon carbide seed crystal, so that a silicon carbide single crystal doped with vanadium grows on the silicon carbide seed crystal, and
in the heating each of the first crucible and the second crucible, a temperature of the powder containing vanadium is lower than a temperature of the silicon carbide powder.

11. The method of manufacturing a silicon carbide substrate according to claim 10, wherein in the heating each of the first crucible and the second crucible, a temperature of the second crucible is controlled independently of a temperature of the first crucible.

12. The method of manufacturing a silicon carbide substrate according to claim 10, wherein the powder containing vanadium is vanadium carbide.

13. The method of manufacturing a silicon carbide substrate according to claim 10, wherein in the heating each of the first crucible and the second crucible, a difference between the temperature of the powder containing vanadium and the temperature of the silicon carbide powder is 200° C. to 400° C.

14. A manufacturing apparatus for a silicon carbide substrate, the manufacturing apparatus comprising:
a first crucible in which silicon carbide powder and a silicon carbide seed crystal are disposed;
a second crucible in which powder containing vanadium is disposed and which is connected to the first crucible; and
a heater configured to heat each of the first crucible and the second crucible such that a temperature of the powder containing vanadium is lower than a temperature of the silicon carbide powder.

15. The manufacturing apparatus for a silicon carbide substrate according to claim 14, wherein the heater includes a first heater unit configured to heat the first crucible and a second heater unit configured to heat the second crucible, and
the second heater unit is controlled independently of the first heater unit.

16. The manufacturing apparatus for a silicon carbide substrate according to claim 14, the manufacturing apparatus further comprising a heat insulator disposed between the first crucible and the second crucible.
